(19) United States
(12) Patent Application Publication
(10) Pub. No.: US 2025/0336432 A1
(43) Pub. Date: Oct. 30, 2025

(54) SEMICONDUCTOR DEVICE HAVING DQS INTERVAL TIMER

(71) Applicant: MICRON TECHNOLOGY, INC., Boise, ID (US)

(72) Inventors: RYO FUJIMAKI, Kanagawa (JP); SHINGO MITSUBORI, Tokyo (JP); YUTAKA UEMURA, Tokyo (JP)

(73) Assignee: MICRON TECHNOLOGY, INC., Boise, ID (US)

(21) Appl. No.: 19/097,679

(22) Filed: Apr. 1, 2025

Related U.S. Application Data
(60) Provisional application No. 63/638,826, filed on Apr. 25, 2024.

(51) Int. Cl. G11C 11/4076

(52) U.S. Cl. CPC G11C 11/4076

(57) ABSTRACT

An example apparatus includes a first circuit configured to activate a first control signal responsive to a second control signal and deactivate the first control signal responsive to a third control signal, a second circuit coupled to the first circuit and configured to output a clock signal when predetermined clock cycles elapsed after the first control signal is activated, and a third circuit coupled to the second circuit and configured to count the clock signal. The third circuit is configured to activate the third control signal when a count value reaches a first value and activate a fourth control signal when a count value reaches a second value greater than the first value. The difference between the second value and the first value is the predetermined clock cycles or less.

### CROSS-REFERENCE TO RELATED APPLICATIONS

This application claims the filing benefit of U.S. Provisional Application No. 63/638,826, filed Apr. 25, 2024. This application is incorporated by reference herein in its entirety and for all purposes.

### BACKGROUND

A DDR5 DRAM includes a DQS interval timer that measures a difference between a propagation time of a data signal and a propagation time of a data strobe signal in a DRAM. The operation for measuring the difference between these propagation times using the DQS interval timer needs to be completed within a period defined by a specification.

### BRIEF DESCRIPTION OF THE DRAWINGS

FIG. 1 is a block diagram for explaining a configuration of a semiconductor memory device according to the present disclosure;

FIG. 2 is a circuit diagram of a data input circuit;

FIG. 3 is a circuit diagram of a DQS interval timer and a DQS interval oscillator,

FIG. 4 is a circuit diagram of a synchronizer;

FIG. 5A is a circuit diagram of an interval counter;

FIG. 5B is a truth table representing operations of adder circuits;

FIG. 6 is a timing chart for explaining operations of the DQS interval timer; and

FIG. 7 is a block diagram showing an example in which the technology according to the present disclosure is applied to a latency shifter.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

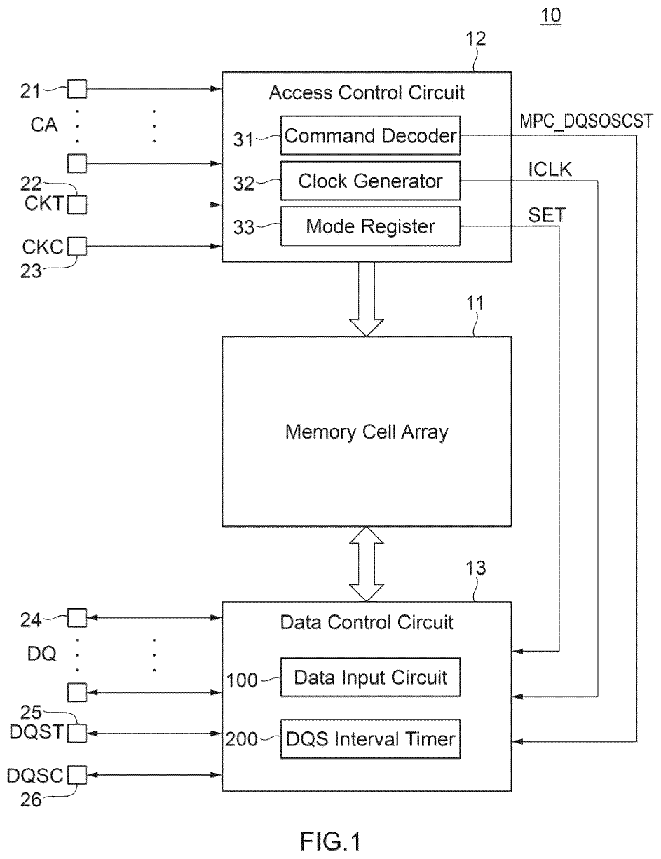

FIG. 1 is a block diagram for explaining a configuration of a semiconductor memory device 10 according to the present disclosure. The semiconductor memory device 10 shown in FIG. 1 is a DDR5 DRAM and includes a memory cell array 11 including a plurality of memory cells, an access control circuit 12 used for accessing the memory cell array 11, a command address terminal 21 to which a command address signal CA is input from outside, and clock terminals 22 and 23 to which complementary external clock signals CKT and CKC are respectively input from outside. The access control circuit 12 includes a command decoder 31, a clock generator 32, and a mode register 33.

The command address signal CA is decoded by the command decoder 31, thereby generating various internal commands. For example, when the command address signal CA indicates a read command, an internal read command is generated by the command decoder 31 and data held in a designated memory cell in the memory cell array 11 is read out. Read data DQ read out from the memory cell array 11 is output from a data input/output terminal 24 to outside via a data control circuit 13. When a read operation is performed, complementary data strobe signals DQST and DQSC are respectively output from the strobe terminals 25 and 26 in synchronization with the read data DQ. When the command address signal CA indicates a write command, an internal write command is generated by the command decoder 31 and write data DQ input from outside to the data input/output terminal 24 is written in a designated memory cell in the memory cell array 11 via the data control circuit 13. When a write operation is performed, the complementary data strobe signals DQST and DQSC are respectively input to the strobe terminals 25 and 26 with the write data DQ.

When the command address signal CA indicates a mode-register set command, an internal mode-register set command is generated by the command decoder 31 and various parameters set in the mode register 33 are overwritten. When the command address signal CA indicates a DQS interval oscillator start command, an internal command MPC_DQSOSCST is generated by the command decoder 31. The internal command MPC_DQSOSCST is supplied to the data control circuit 13.

The external clock signals CKT and CKC are input to the clock generator 32 included in the access control circuit 12. The clock generator 32 generates an internal clock signal ICLK based on the external clock signals CKT and CKC. Operations of the access control circuit 12 and the data control circuit 13 are performed in synchronization with the internal clock signal ICLK.

The data control circuit 13 includes a data input circuit 100 and a DQS interval timer 200.

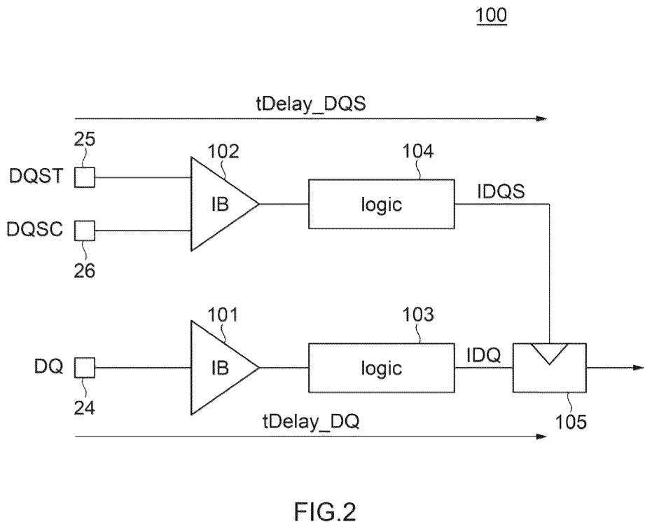

FIG. 2 is a circuit diagram of the data input circuit 100. As shown in FIG. 2, the data input circuit 100 includes an input buffer 101 that receives the write data DQ input from outside via the data input/output terminal 24 and an input buffer 102 that receives the complementary data strobe signals DQST and DQSC respectively input from outside via the strobe terminals 25 and 26. An output signal of the input buffer 101 is supplied to a data input node of a data latch circuit 105 via a logic circuit 103. An output signal of the input buffer 102 is supplied to a clock input node of the data latch circuit 105 via a logic circuit 104. With this configuration, internal write data IDQ transmitted via the input buffer 101 and the logic circuit 103 is synchronized with a strobe signal IDQS transmitted via the input buffer 102 and the logic circuit 104 and latched on the data latch circuit 105. In a DDR5 DRAM, an intrinsic delay tDelay_DQ of the input buffer 101 and the logic circuit 103 and an intrinsic delay tDelay_DQS of the input buffer 102 and the logic circuit 104 do not need to match each other.

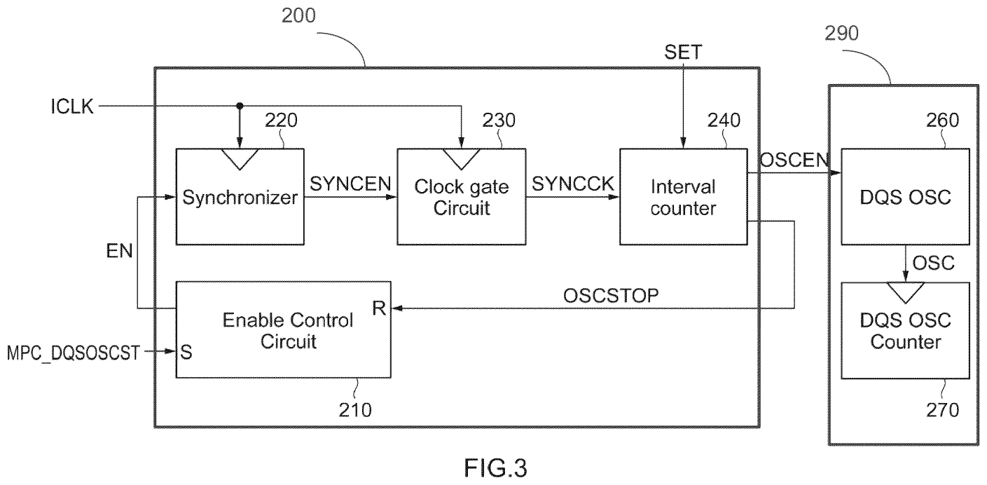

FIG. 3 is a circuit diagram of the DQS interval timer 200 and a DQS interval oscillator 290. As shown in FIG. 3, the DQS interval timer 200 includes an enable control circuit 210 that generates an enable signal EN. The enable control circuit 210 is set in synchronization with the internal command MPC_DQSOSCST and is reset in synchronization with a stop signal OSCSTOP. During a period where the enable control circuit 210 is being set, the enable signal EN is activated. The enable signal EN is supplied to a synchronizer 220.

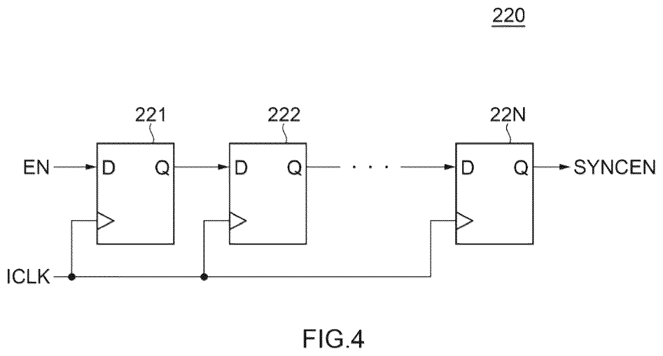

FIG. 4 is a circuit diagram of the synchronizer 220. As shown in FIG. 4, the synchronizer 220 is constituted of a plurality of cascade-connected flip flop circuits. In the example shown in FIG. 4, the synchronizer 220 is constituted of N latch circuits formed from a first stage flip flop circuit 221 that receives the enable signal EN to a final stage flip flop circuit 22N that outputs an enable signal SYNCEN. These flip flop circuits 221 to 22N are respectively synchronized with the internal clock signal ICLK to perform a latch operation. With this configuration, the enable signal SYNCEN output from the final stage flip flop circuit 22N is in synchronization with the internal clock signal ICLK. The enable signal SYNCEN is supplied to a clock gate circuit 230 shown in FIG. 3. When the enable signal SYNCEN is activated, the clock gate circuit 230 lets the internal clock signal ICLK pass through, thereby outputting an internal clock signal SYNCCK that is in synchronization with the internal clock signal ICLK. The internal clock signal SYNCCK is supplied to an interval counter 240. As shown in FIG. 3, the DQS interval timer 200 includes the enable control circuit 210, the synchronizer 220, the clock gate circuit 230 and the interval counter 240.

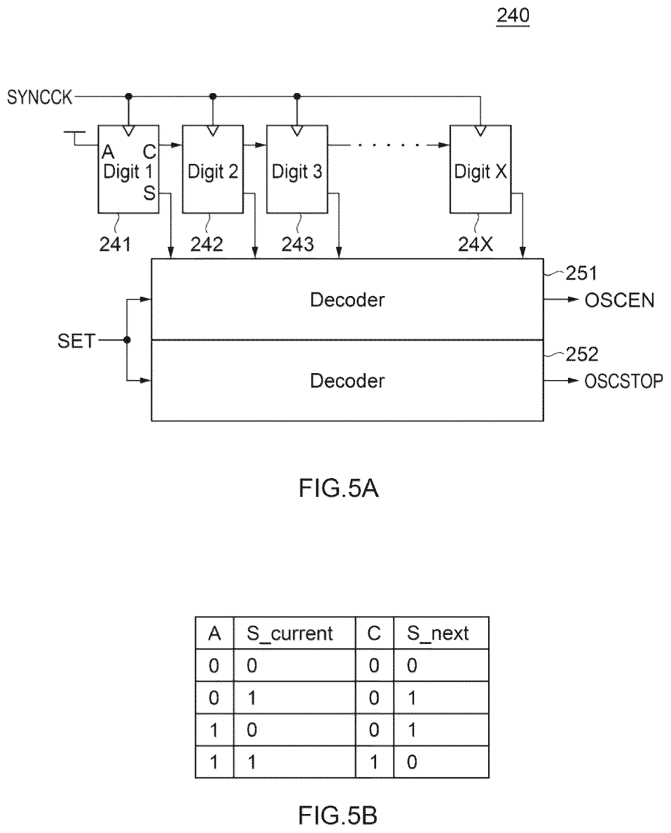

FIG. 5A is a circuit diagram of the interval counter 240. As shown in FIG. 5A, the interval counter 240 includes a plurality of cascade-connected adder circuits 241 to 24X and decoders 251 and 252. In the example shown in FIG. 5A, X adder circuits formed from a first stage adder circuit 241 to a final stage adder circuit 24X are included in the interval counter 240. Each of the adder circuits 241 to 24X includes an input node A, output nodes C and S, and a clock node. The internal clock signal SYNCCK is commonly supplied to each clock node of the adder circuits 241 to 24X. The truth table representing operations of the adder circuits 241 to 24X is as shown in FIG. 5B. With this configuration, the adder circuits 241 to 24X function as binary counters that perform counting operations in synchronization with the internal clock signal SYNCCK. Count values of the adder circuits 241 to 24X are supplied to the decoders 251 and 252. The decoder 251 activates an enable signal OSCEN when the count values of the adder circuits 241 to 24X exceed an initial value, and deactivates the enable signal OSCEN when the count values of the adder circuits 241 to 24X reach a set value M. The set value M is not a fixed value and is variable based on a parameter SET set in the mode register 33. Further, the decoder 252 activates the stop signal OSCSTOP when the count values of the adder circuits 241 to 24X reach a set value K. The set value K is a value less than M and a value equal to or more than M-N. As described above, N is the number of flip flop circuits 221 to 22N constituting the synchronizer 220. Therefore, the set value K is also variable based on the parameter SET set in the mode register 33. The stop signal OSCSTOP generated by the interval counter 240 is supplied to the enable control circuit 210. The enable signal OSCEN generated by the interval counter 240 is supplied to a DQS oscillator 260.

During a period where the enable signal OSCEN is activated, the DQS oscillator 260 generates an oscillator signal OSC. The period of the oscillator signal OSC is designed to match the difference between the intrinsic delay tDelay_DQ and the intrinsic delay tDelay_DQS described with reference to FIG. 2. The oscillator signal OSC is supplied to a DQS OSC counter 270. The DQS OSC counter 270 counts the oscillator signal OSC. As shown in FIG. 3, the DQS interval oscillator 290 includes the DQS oscillator 260 and the DQS OSC counter 270.

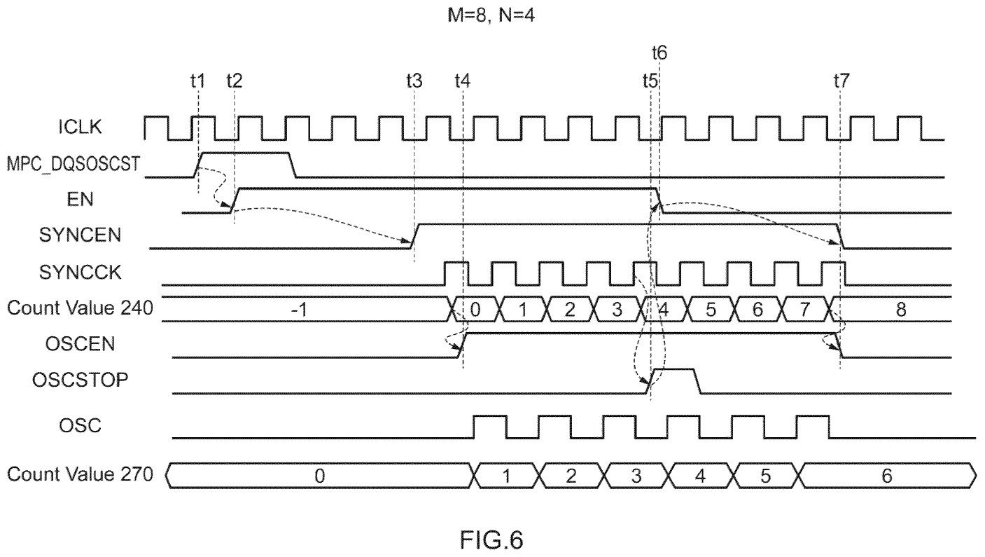

FIG. 6 is a timing chart for explaining operations of the DQS interval timer 200. In the example shown in FIG. 6, a case where the set value Mis 8 and the number N of the flip flop circuits 221 to 22N constituting the synchronizer 220 is 4 is shown. First, when the internal command MPC_DQSOSCST is activated at a time t1, the enable control circuit 210 activates the enable signal EN. The activation timing of the enable signal EN is a time t2. The enable signal EN is input to the synchronizer 220 and the enable signal SYNCEN is activated at a time t3 where the enable signal EN has passed through the flip flop circuits 221 to 22N constituting the synchronizer 220. In the example shown in FIG. 6, since N is 4, the period between the time t2 and the time t3 is approximately four clock cycles.

When the enable signal SYNCEN is activated, the clock gate circuit 230 lets the enable clock signal ICLK pass through, thereby starting to output the internal clock signal SYNCCK. The internal clock signal SYNCCK is counted by the interval counter 240. In the example shown in FIG. 6, the initial value of the interval counter 240 is −1, and when the count value becomes 0 on the first count, the enable signal OSCEN is activated. The activation timing of the enable signal OSCEN is a time t4. When the enable signal OSCEN is activated, the DQS oscillator 260 is activated and oscillation of the oscillator signal OSC is started. The oscillator signal OSC is counted by the DQS OSC counter 270.

When counting up of the interval counter 240 is proceeded and its count value reaches M-N (=4) at a time t5, the stop signal OSCSTOP is activated. In response to this, the enable control circuit 210 deactivates the enable signal EN immediately. The deactivation timing of the enable signal EN is a time t6 immediately after the time t5. However, even when the enable signal EN is deactivated, the enable signal SYNCEN is not deactivated immediately, so that during a period until the enable signal SYNCEN is deactivated, clocking of the internal clock signal SYNCCK is continued and counting up of the interval counter 240 is proceeded. Subsequently, when the count value of the interval counter 240 reaches M (=8) at a time t7, the enable signal OSCEN is deactivated. When the enable signal OSCEN is deactivated, the DQS oscillator 260 stops oscillation of the oscillator signal OSC. With this process, the counting operation performed by the DQS OSC counter 270 is ended. In the example shown in FIG. 6, the count value of the DQS OSC counter 270 is stopped at 6. The count value of the DQS OSC counter 270 is transferred to an external controller, and the external controller can detect a difference between the intrinsic delay tDelay_DQ and the intrinsic delay tDelay_DQS based on the count value of the DQS OSC counter 270. As a result, based on the difference between intrinsic delays in the DRAM described above, timings of the write data DQ and the data strobe signals DQST and DQSC are adjusted on the controller side, thereby offsetting the difference between intrinsic delays in the DRAM to perform a smooth operation.

As described above, since the semiconductor memory device according to the present embodiment activates the stop signal OSCSTOP before the interval counter 240 deactivates the enable signal OSCEN, the enable control circuit 210 is reset quickly. Accordingly, a period where a DQS interval monitor command can be accepted from outside is shortened. For example, in the example shown in FIG. 6, as compared to a case where the stop signal OSCSTOP is activated simultaneously with deactivation of the enable signal OSCEN, the period where a DQS interval monitor command can be accepted is shortened for four clock cycles. Further, during a period until the enable signal EN deactivated with the stop signal OSCSTOP passes through the synchronizer 220, a state where the enable signal SYNCEN is activated is maintained, so that counting operations of the interval counter 240 are performed normally.

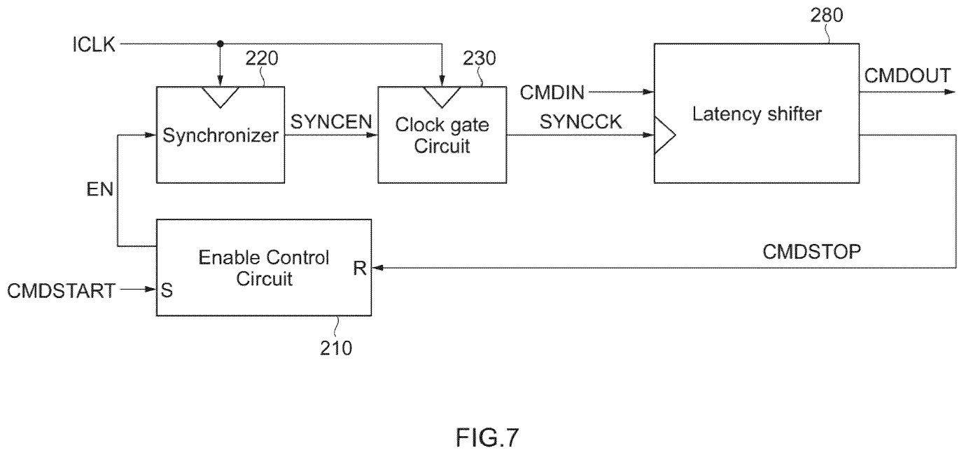

FIG. 7 is a block diagram showing an example in which the technology according to the present disclosure is applied to a latency shifter. The circuit shown in FIG. 7 has a configuration in which a latency shifter 280 is provided instead of the interval counter 240 shown in FIG. 3. The latency shifter 280 generates an internal command CMDOUT by synchronizing with the internal clock signal SYNCCK to delay an internal command CMDIN for predetermined clock cycles. Even with such a circuit configuration, by generating a stop signal CMDSTOP before outputting the internal command CMDOUT, it is possible to shorten the cycle where an internal command CMDSTART can be input to the enable control circuit 210.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a first circuit configured to activate a first control signal responsive to a second control signal and deactivate the first control signal responsive to a third control signal;
a second circuit coupled to the first circuit and configured to output a clock signal when predetermined clock cycles elapsed after the first control signal is activated; and
a third circuit coupled to the second circuit and configured to count the clock signal,
wherein the third circuit is configured to activate the third control signal when a count value reaches a first value and activate a fourth control signal when a count value reaches a second value greater than the first value, and
wherein a difference between the second value and the first value is the predetermined clock cycles or less.

2. The apparatus of claim 1,
wherein the second circuit includes a plurality of flip flop circuits cascade connected, and
wherein the difference between the second value and the first value is a number of the plurality of flip flop circuits or less.

3. The apparatus of claim 1, wherein the difference between the second value and the first value is the same as the predetermined clock cycles.

4. The apparatus of claim 3,
wherein the second circuit includes a plurality of flip flop circuits cascade connected, and
wherein the difference between the second value and the first value is the same as a number of the plurality of flip flop circuits.

5. The apparatus of claim 1, further comprising a fourth circuit coupled to the third circuit and configured to generate an oscillation signal until the count value reaches the second value.

6. The apparatus of claim 5, further comprising a fifth circuit coupled to the fourth circuit and configured to count the oscillation signal.

7. The apparatus of claim 6, further comprising a data input circuit including:
a first input circuit configured to generate an internal data signal responsive to an external data signal;
a second input circuit configured to generate an internal data strobe signal responsive to an external data strobe signal; and
a data latch circuit configured to latch the internal data signal responsive to the internal data strobe signal,
wherein a difference between a delay time of the first input circuit and a delay time of the second input circuit is the same as a clock cycle of the oscillation signal.

8. The apparatus of claim 1, further comprising a command decoder configured to activate the second control signal when a predetermined command is issued from outside.

9. The apparatus of claim 1, further comprising a mode register configured to designate the second value.

10. An apparatus comprising:
a control circuit configured to start generating a clock signal when N clock cycle elapsed after a first signal is activated and stop generating the clock signal when N clock cycle elapsed after a second signal is activated; and
a first counter circuit configured to count the clock signal, deactivate a third signal when a count value reaches M, and activate the second signal when the count value reaches K,
wherein K is less than M and equal to or more than M-N.

11. The apparatus of claim 10, wherein K is M-N.

12. The apparatus of claim 10, further comprising an oscillation circuit configured to generate an oscillation signal until the count value reaches M.

13. The apparatus of claim 12, further comprising a second counter circuit configured to count the oscillation signal.

14. The apparatus of claim 13, further comprising a data input circuit including:
a first input circuit configured to generate an internal data signal responsive to an external data signal;
a second input circuit configured to generate an internal data strobe signal responsive to an external data strobe signal; and
a data latch circuit configured to latch the internal data signal responsive to the internal data strobe signal,
wherein a difference between a delay time of the first input circuit and a delay time of the second input circuit is the same as a clock cycle of the oscillation signal.

15. The apparatus of claim 10, further comprising a command decoder configured to activate the first signal when a predetermined command is issued from outside.

16. The apparatus of claim 10, further comprising a mode register configured to designate a value of M.

17. An apparatus comprising:
an enable control circuit configured to activate a first enable signal responsive to a start signal and deactivate the first enable signal responsive to an end signal;
a plurality of cascade-connected flip flop circuits configured to shift the first enable signal responsive to a first clock signal to generate a second enable signal;
a clock gate circuit configured to generate a second clock signal responsive to the second enable signal; and
a counter circuit configured to count the second clock signal, generate a third enable signal when a count value reaches a first value, and generate the end signal before the count value reaches the first value.

18. The apparatus of claim 17, wherein the counter circuit is configured to generate the end signal when the count value reaches a second value.

19. The apparatus of claim 18, wherein a difference between the first value and the second value is a number of the plurality of cascade-connected flip flop circuits or less.

20. The apparatus of claim 19, wherein the difference between the first value and the second value is the same as the number of the plurality of cascade-connected flip flop circuits.
